(19) United States
(12) Patent Application Publication
(10) Pub. No.: US 2018/0038578 A1
(43) Pub. Date: Feb. 8, 2018

(54) FLEXIBLE LIGHTING PANEL

(71) Applicant: TEDDYKOREA CO., LTD., Seoul (KR)

(72) Inventor: Yeong-hee SON, Seoul (KR)

(73) Assignee: TEDDYKOREA CO., LTD., Seoul (KR)

(21) Appl. No.: 15/552,805

(22) PCT Filed: Feb. 17, 2015
(86) PCT No.: PCT/KR2016/001586

§ 371 Date: Aug. 23, 2017

(30) Foreign Application Priority Data
Feb. 24, 2015 (KR) 10-2015-0025593
May 14, 2015 (KR) 10-2015-0067217

(51) Int. Cl. F21V 17/00; F21V 29/70; F21V 29/89; H05B 33/08; F21V 23/06; H05K 3/28; F21K 9/64; F21V 3/00; F21V 31/00; H05K 1/03; H05K 3/06; F21V 19/00; F21V 23/00

(52) U.S. Cl. CPC F21V 17/007; F21V 19/0015; F21V 29/70; F21V 29/89; H05B 33/0857; F21V 23/06; F21V 23/001; F21K 9/64; F21V 3/00; F21V 31/00; H05K 1/0326; H05K 1/0393; H05K 3/06; H05K 3/28; F21Y 2113/13

(57) ABSTRACT

A flexible lighting panel includes: a base layer having one side surface on which a circuit pattern is disposed and made of a flexible material; a plurality of LEDs mounted on one side surface of the base layer; and a heat dissipating layer laminated on the other side surface of the base layer.

### TECHNICAL FIELD

The present invention relates to a flexible lighting panel, and more particularly, to a flexible lighting panel, which is capable of being stored in a folded or rolled state because the flexible light panel does not have directivity, preventing a light interference phenomenon from occurring, and easily dissipating heat generated by a plurality of LEDs through a heat dissipating layer.

### BACKGROUND ART

Lighting are widely used in the film or image fields in order to shoot at a place where there is not enough light or to produce different atmospheres. Such a lighting is provided in various kinds and forms according to use purposes thereof.

For example, lighting devices including a fluorescent lamp, a halogen lamp, a discharge lamp, a metal halide lamp, and the like are being used as lighting devices used in the outdoor or studio for photography and movie shooting.

Such a lighting device includes a support and a flat housing installed on an upper portion of the support as basic components. A single lamp or a plurality of lamps may be installed in the flat housing, and a light collecting plate may be installed on a front end of the housing so that light of the lamp is concentratedly irradiated in an opened direction.

However, most of the lamps used in general lighting devices are high-power consuming products having power of 200 W to 2 kW, and the lifespan of the lamps is not only about 3,000 hours to 9,000 hours, but also significantly varies depending on a state of the lamp during broadcasting and photographing.

Thus, since the lamp used in the lighting device may change in color temperature when the lamp is used for a predetermined time event though a usable time of the lamp is left, it is often the case that a replacement period of the lamp has to be shorter than a reference usable time, and thus, lamp replacement costs may increase.

In addition, the lighting device using the halogen lamp generates strong radiant heat together with light in use, a skin of a subject may be damaged during the broadcast shooting or photography shooting, and also, the lighting device may be malfunctioned or damaged due to the strong heat.

As described above, since the lighting device using the halogen lamp has an in convenience that it is necessary to separately provide air conditioning facilities for preventing the abovementioned problems, in order to solve this inconvenience, a lighting device using a three-wavelength lamp, which has high power efficiency and low heat generation has been developed.

However, the lighting device for broadcasting and photographing requires total luminous flux of 20,000 lumens or more, but the above-described three-wavelength lamp does not satisfy the total luminous flux.

Furthermore, in recent years, lighting devices using a light emitting diode (LED) having light efficiency have been developed. Such a lighting device using the LED is very efficient and economical because it has a half energy consumption rate and lifespan longer ten times or more than that of the conventional lighting device.

FIG. 1 is a photograph of a conventional LED lighting device. The LED lighting device includes a support and a sturdy and flat housing installed on an upper portion of the support as basic components. A printed circuit board is installed in the flat housing, a plurality of LED modules are installed on the printed circuit board, and a light-transmitting panel is installed on a front end of the housing so that the printed circuit board and the LED modules are not exposed to the outside.

However, since the above-described LED lighting device is generally formed in a fixed rectangular shape and has to be maintained to a high level of total luminous flex, several tens or hundreds of LED modules are installed, and thus, the LEE lighting device has an overall large appearance.

Thus, it is inconvenient to use a vehicle having a large loading space such as a truck or the like at the time of transportation. In addition, since the above-described lighting device has the fixed outer appearance, it is not easy to expand the LED lighting device. Also, in order to provide a high level of brightness, several LED lighting devices have to be used together.

To solve the abovementioned problems, a lighting device using a foldable type LED, which is capable of being folded to occupy a small volume as occasion demands so as to improve storage, transportability, and portability and reduce power consumption, has been disclosed in Korean Patent Registration No. 10-1120460.

However, since the lighting device as described above is configured so that a plurality of printed circuit boards are disposed to be spaced apart from each other, the lighting device may be stored by being rolled in a cylindrical shape, but may not folded in a longitudinal direction of the printed circuit board.

Korean Patent Registration No. 10-1120460 (Feb. 20, 2012)

### DISCLOSURE OF THE INVENTION

### Technical Problem

To solve the problems according to the related art, an object of the prevention is to provide a flexible lighting panel, which is capable of being stored in a folded or rolled state because the flexible light panel does not have directivity, preventing a light interference phenomenon from occurring, and easily dissipating heat generated by a plurality of LEDs through a heat dissipating layer.

### Technical Solution

To solve the abovementioned technical problems, a flexible lighting panel according to an embodiment of the present invention includes: a base layer having one side surface on which a circuit pattern is disposed and made of a flexible material; a plurality of LEDs mounted on one side surface of the base layer; and a heat dissipating layer laminated on the other side surface of the base layer.

Preferably, the heat dissipating layer may have a plate-like structure having a net structure or a honeycomb structure.

Preferably, the heat dissipating layer may be made of a copper or aluminum material.

Preferably, at least one fiber layer may be laminated on the other side surface of the heat dissipating layer.

Preferably, the fiber layer may be treated to be flame-retarded or waterproofed.

Preferably, the plurality of LEDs may include at least two groups, and each of the groups may have a different color temperature.

Preferably, the plurality of LEDs may include a first group of LEDs having a color temperature of 2,500 K to 3,500 K and a second group of LEDs having a color temperature of 4,500 K to 6,500 K, and the first group of LEDs and the second group of LEDs may be lattice-arranged adjacent to each other.

Preferably, the plurality of LEDs may include a first group of LEDs having a color temperature of 2,800 K and a second group of LEDs having a color temperature of 6,500 K, and the flexible lighting panel may further include a control unit including a level adjustment module configured to adjust the color temperatures of the first and second groups in stages and a fine adjustment module configured to control current supplied to the first and second groups, which are adjusted in level by the level adjustment module to finely adjust the color temperatures.

Preferably, the plurality of LEDs may include RGB LEDs, and the flexible lighting panel may further include a control unit configured to control colors and turn on/off of the plurality of LEDs.

Preferably, the flexible lighting panel may further include: a spacer layer laminated on a top surface of the base layer except for the plurality LEDs; and a transparent cover layer configured to cover and seal the spacer layer and the LEDs.

Preferably, a UV blocking agent or a phosphor resin may be applied inside the transparent cover layer.

Preferably, the spacer layer may have a thickness corresponding to a formation height of each of the LEDs.

Preferably, each of the base layer and the heat dissipating layer may have a flat rectangular shape of which corner portions are rounded or chamfered, and the flexible lighting panel may further include a finishing member configured to surround edges of the base layer and the heat dissipating layer.

Preferably, the finishing member may include a connection unit connecting the adjacent flexible lighting panels to each other.

Preferably, the base layer may include: a flexible board made of a flexible synthetic resin material; a silicon layer laminated on at least one side surface of the flexible board; and a circuit pattern formed on a top surface of the silicon layer.

Preferably, the silicon layer may have shore hardness of 70 to 100.

Preferably, the circuit pattern may be formed through an etching process after a meal layer is laminated on the top surface of the silicon layer through a roll-to-roll process.

Preferably, when the board is made of polyethylene terephthalate (PET) or polyethylene naphthalate (PEN), a temperature for the roll-to-roll process may be 120° to 170°, and when the board is made of polyimide (PI), a temperature for the roll-to-roll process may be 180° to 230°.

Preferably, ink containing an alkyd resin may be applied to the top surface of the silicon layer on which the circuit pattern is not formed.

Preferably, the silicon layer may have a formation thickness of 20 μm to 35 μm.

To solve the abovementioned technical problems, a flexible lighting panel according to another embodiment of the present invention includes: a base layer having a top surface on which a circuit pattern is disposed and made of a flexible material; a plurality of LEDs mounted on the base layer so as to be electrically connected to the circuit pattern; a black sheet layer laminated on the top surface of the base except for the plurality of LEDs; and a transparent cover layer configured to cover and seal the black sheet and the LEDs.

Preferably, the base layer may be made of a fiber material.

Preferably, the base layer may be treated to be flame-retarded or waterproofed.

Preferably, the transparent cover layer may include a UV blocking agent.

Preferably, the plurality of LEDs may include at least two groups, and each of the groups may have a different color temperature.

Preferably, the plurality of LEDs may include a first group of LEDs having a color temperature of 2,500 K to 3,500 K and a second group of LEDs having a color temperature of 4,500 K to 6,500 K, and the first group of LEDs and the second group of LEDs may be lattice-arranged adjacent to each other.

Preferably, each of the base layer, the black sheet layer, and the transparent cover layer may have a flat rectangular shape of which corner portions are rounded or chamfered, and the flexible lighting panel may further include a finishing member configured to surround edges of the base layer, the black sheet layer, and the transparent cover layer.

Preferably, a power supply electrode configured to supply power to the plurality of LEDs, a power supply cable connected to the power supply electrode, and a cable fixing tool configured to fix and support a portion of the power supply cable connected to the power supply electrode may be disposed on a bottom surface of the base layer.

Preferably, the plurality of LEDs may include a first group of LEDs having a color temperature of 2,800 K and a second group of LEDs having a color temperature of 6,500 K, and the flexible lighting panel may further include a control unit including a level adjustment module configured to adjust the color temperatures of the first and second groups in stages and a fine adjustment module configured to control current supplied to the first and second groups, which are adjusted in level by the level adjustment module to finely adjust the color temperatures.

Preferably, the plurality of LEDs may include RGB LEDs, and the flexible lighting panel may further include a control unit configured to control colors and turn on/off of the plurality of LEDs.

Preferably, a thermoplastic resin layer may be further disposed between the base layer and the black sheet layer.

### Advantageous Effects

As described above, the present invention is advantageous in that the flexible display panel is stored in the folded or rolled state, and the black sheet layer absorbs a portion of the light emitted to the rear surface of the LED to prevent the light interference from occurring.

Also, there is an advantage that the UV blocking agent is contained in the transparent cover layer to prevent the discoloration from occurring by the sunlight even after a long period of time.

Also, there is an advantage that the LED having a color temperature of 2,500 K to 3,500 K and the LED having a color temperature of 4,500 K to 6,500 K are combined to express various color temperatures.

Also, there is an advantage that the flexible lighting panel has a planar rectangular shape of which the corner portions are rounded to easily and quickly perform the stapling process.

Also, there is an advantage that the cable is prevented from being from the electrode for the power supply by pulling the cable through the cable fixing tool.

Also, there is an advantage that the plurality of LEDs are constituted by the RGB LEDs to express the various colors and also express the characters, the figures, and the like through the control unit.

Also, there is an advantage that the black sheet layer is formed with a thickness corresponding to the formation height of the LED to prevent the transparent cover layer from being lifted by the formation height of the LED.

The present invention as described above has an advantage that the heat generated from the plurality of LEDs is easily dissipated through the heat dissipating layer.

Particularly, there is an advantage that the heat dissipating layer is formed with the plate-like structure having the net structure or the honeycomb structure to widen the heat dissipating area, thereby realizing the superior heat dissipating efficiency and maximizing the heat dissipating effect through the dissipation of the heat between the heat dissipating layers.

Also, there is an advantage that the fiber layer provided on the other surface of the heat dissipating layer is flame-retarded or waterproofed to be resistant to heat and moisture infiltration.

Also, there is an advantage that the ink having the black color is applied to the silicon layer, on which the circuit pattern is not formed, to absorb a portion of the light emitted to the rear surface, thereby preventing the light interference from occurring.

Particularly, there is an advantage that the ink containing the alkyd resin as the link is applied to a thickness of 20 μm to 35 μm to prevent the cracking from occurring after drying the applied ink.

Also, there is an advantage that the LED is mounted by using the base layer, to which the silicon layer is applied, to give the high-temperature resistant characteristics.

Also, there is an advantage that the spacer layer is formed with a thickness corresponding to the formation height of the LED to prevent the transparent cover layer from being lifted by the formation height of the LED.

### BRIEF DESCRIPTION OF THE DRAWINGS

FIG. 1 is a photograph of an LED lighting device according to a related art.

FIG. 2 is a perspective view of a foldable type LED lighting device according to the related art.

FIG. 3 is a perspective view illustrating a front surface of a flexible lighting panel according to an embodiment of the present invention.

FIG. 4 is a perspective view illustrating a rear surface of the flexible lighting panel according to an embodiment of the present invention.

FIG. 5 is an exploded perspective view of the flexible lighting panel according to an embodiment of the present invention.

FIG. 6 is a cross-sectional view illustrating a portion of a cross-section of the flexible lighting panel according to an embodiment of the present invention.

FIG. 7 is a cross-sectional view illustrating a portion of a cross-section of a flexible lighting panel according to another embodiment of the present invention.

FIG. 8 is a perspective view illustrating a front surface of a flexible lighting panel according to an embodiment of the present invention.

FIG. 9 is a perspective view illustrating a rear surface of the flexible lighting panel according to an embodiment of the present invention.

FIG. 10 is an exploded perspective view of the flexible lighting panel according to an embodiment of the present invention.

FIG. 11 is a cross-sectional view illustrating a cross-section of the flexible lighting panel according to an embodiment of the present invention.

FIG. 12 is a plan view of a flexible lighting panel according to another embodiment of the present invention.

FIG. 13 is a plan view of a flexible lighting panel according to further another embodiment of the present invention.

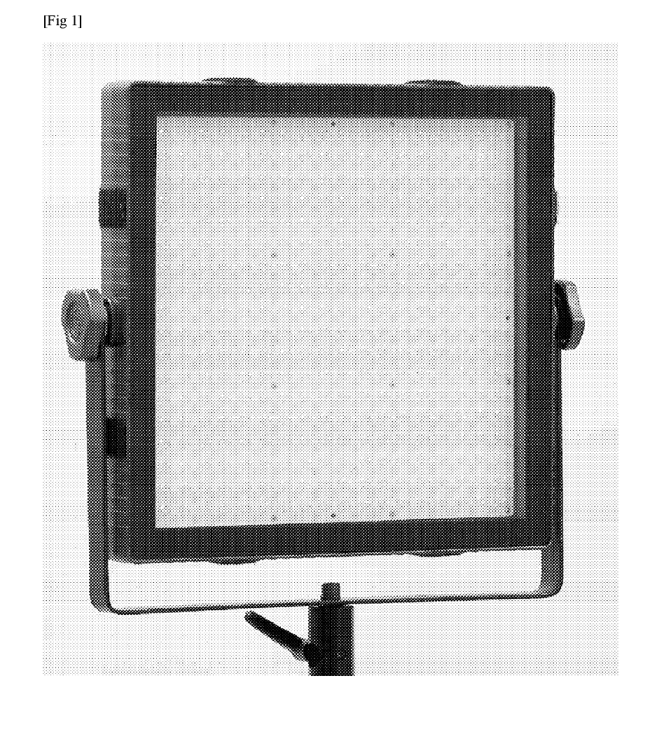

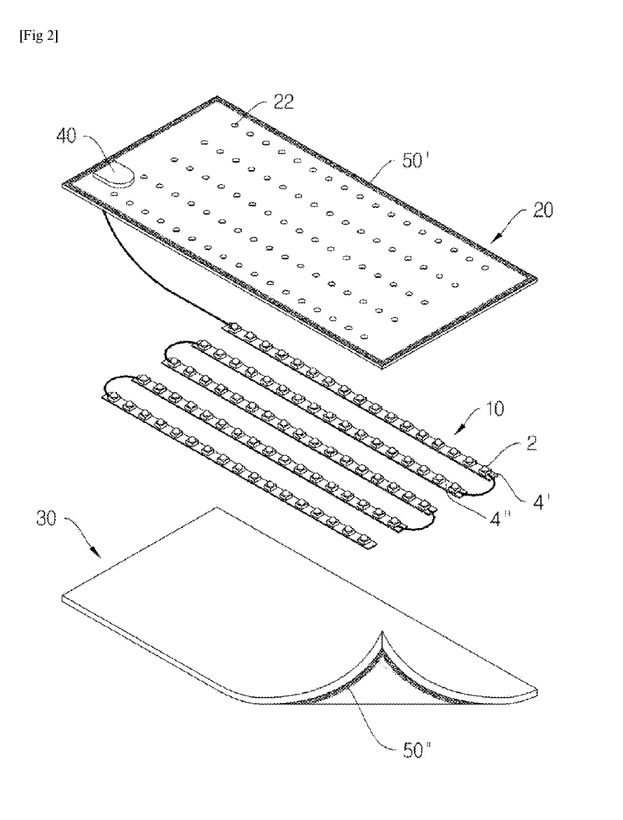

### MODE FOR CARRYING OUT THE INVENTION

The present invention may be carried out in various embodiments without departing from the technical ideas or primary features. Therefore, the above-described embodiments are merely illustrative of the present invention, but should not be limitedly interpreted.

Description will now be given in detail according to exemplary embodiments disclosed herein, with reference to the accompanying drawings. For the sake of brief description with reference to the drawings, the same or equivalent components may be provided with the same reference numbers, and description thereof will not be repeated.

### An Embodiment

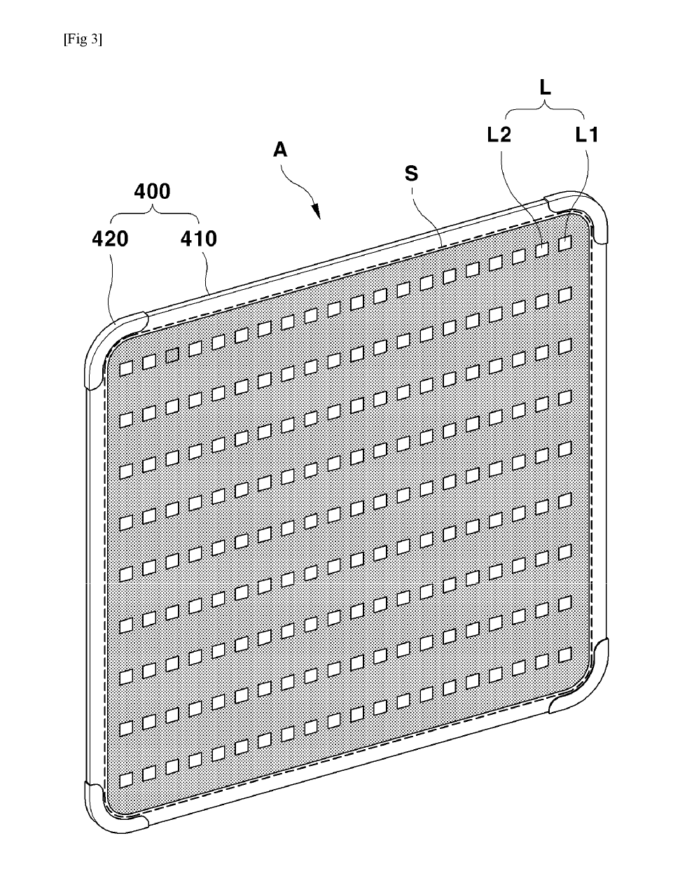

As illustrated in FIGS. 3 to 5, a flexible lighting panel A according to an embodiment of the present invention includes a base layer 100, a plurality of LEDs L, a black sheet layer 200, a transparent cover layer 300, and a control unit (not shown).

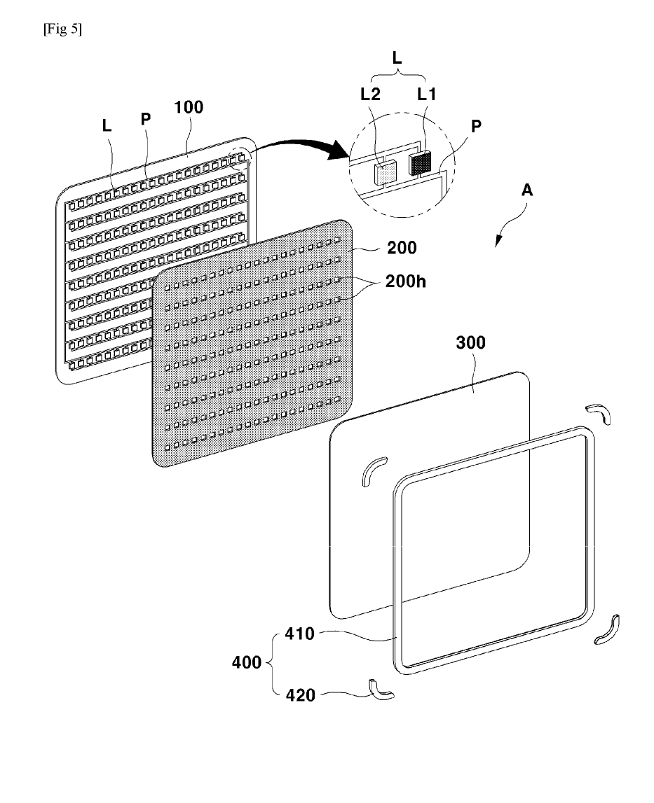

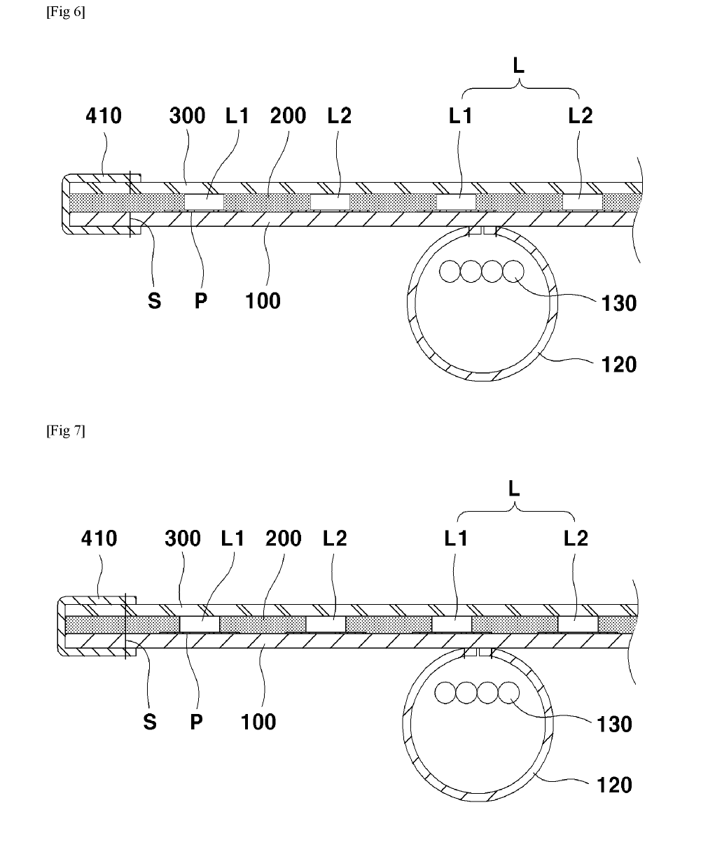

As illustrated in FIG. 5, a circuit pattern P electrically connected to the plurality of LEDs L is formed on a top surface of the base layer 100 and made of a flexible material such as a fiber material so that the flexible lighting panel A according to this embodiment has a flexible property.

The base layer the base layer 100 made of the fiber material may be flame-retarded or waterproofed and thus have a strong heat-resistant property and a waterproof property.

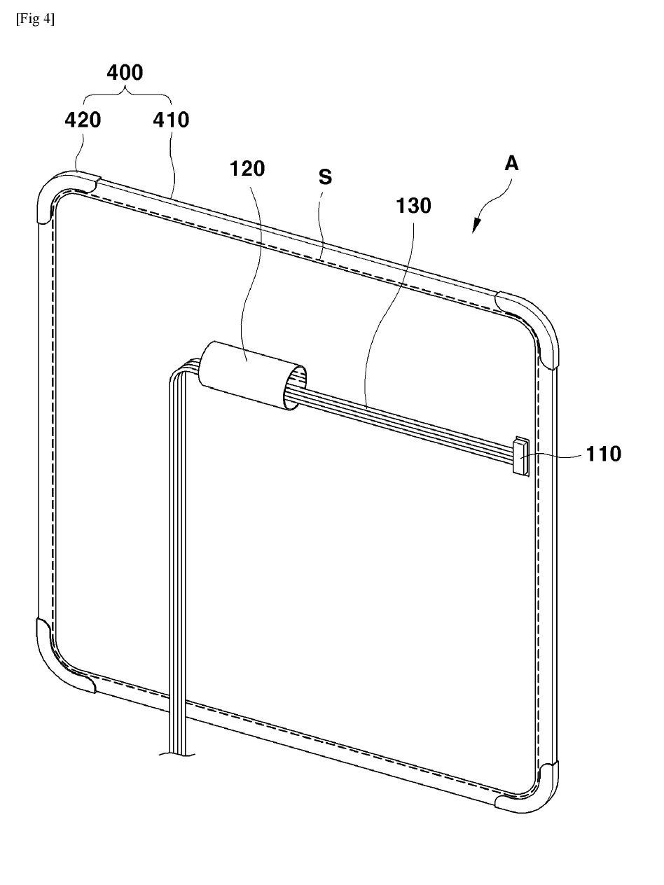

Also, as illustrated in FIG. 4, a power supply electrode 110, which supplies power to the plurality of LEDs L, a power supply cable 130 connected to the power supply electrode 110, and a cable fixing tool 120 for fixing and supporting a portion of the power supply cable 130 connected to the electrode are disposed on a bottom surface of the base layer 100.

The cable fixing tool 120 may prevent an end of the power supply cable 130 from being separated from the power supply electrode 110 by pulling the power supply cable 130.

The plurality of LEDs L is mounted on the base layer 100 so as to be electrically connected to the circuit pattern P.

The plurality of LEDs L may be constituted by at least two groups, and each of the groups has a different color temperatures.

The plurality of LEDs L include a first group of LEDs L1 having a color temperature of 2,500 K to 3,500 K and a second group of LEDs L2 having a color temperature of 4,500 K to 6,500 K. For example, the plurality of LEDs L may be constituted by a first group of LEDs L1 having a color temperature of 3,000 K and a second group of LEDs L2 having a color temperature of 5,000 K.

As illustrated in FIG. 5, the first group of LEDs L1 and the second group of LEDs L2 may be lattice-arranged adjacent to each other.

The black sheet layer 200 is configured to be laminated on the top surface of the base layer 100 except for the plurality of LEDs L and has through-holes 200h corresponding to positions of the plurality of LEDs L.

The black sheet layer 200 may be attached to the top surface of the base layer 100 through a unit such as an adhesive.

To prevent the transparent cover layer 300 from being lift by a formation height of each of the LEDs L, it is preferable that the black sheet layer 200 has a formation thickness corresponding to the formation height of the LED L.

The transparent cover layer 300 is a portion that covers and seals the black sheet layer 200 and the LEDs L. It is preferable that the transparent cover layer 300 is made of a material having a high light-transmitting property and a superior waterproof property.

For example, the transparent cover layer 300 may be made of a material in which at least one synthetic fiber such as polypropylene, polyester, polyethylene, polyvinyl chloride, and the like is mixed.

The transparent cover layer 300 may be attached in a lamination manner.

It is preferable that a UV blocking agent is contained in the transparent cover layer 300. Thus, the transparent cover layer 300 may be prevented from be discolored by sunlight even though the transparent cover layer 300 is used for a long time in the outdoor space.

As described above, a finishing member 400 surrounding edges of the base layer 100, the black sheet layer 200, and the transparent cover layer 300 may be provided to maintain the laminated configuration of the base layer 100, the black sheet layer 200, and the transparent cover layer 300.

The finishing member 400 may include a finishing taping member 410 made of a cloth material, which entirely surrounds the edges of the base layer 100, the black sheet layer 200, and the transparent cover layer 300, and a finishing bracket 420 made of a metal material, which protects each of corner portions.

Each of the corner portions of the base layer 100, the black sheet layer 200, and the transparent cover layer 300 may have a rounded or chamfered shape. For example, the corner portion may be easily and quickly stapled by using a stapling thread S due to the shape as illustrated in FIGS. 3 and 4.

The control unit (not shown) may be built in the flexible lighting panel A of this embodiment or be connected to the flexible lighting panel A of this embodiment through a separate cable.

The control unit may control the LEDs L to adjust the color temperatures of the first group of LEDs L1 having the color temperature of 2,500 K to 3,500 K and the second group of LEDs having the color temperature of 4,500 K to 6,500 K. Thus, colors of the first group of LEDs L1 having the color temperature of 2,500 K to 3,500 K and the second group of LEDs having the color temperature of 4,500 K to 6,500 K may be mixed with each other to realize various color temperatures.

The control unit may include a level adjustment module and a fine adjustment module. For example, when the LEDs include the first group of LEDs L1 having the color temperature of 3,000 K and the second group of LEDs L2 having the color temperature of 5,000 K, the level adjustment module may control the color temperature by following levels.

First level: first group of LEDs L1 brightness 100%+second group of LEDs L2 0%

Second level: first group of LEDs L1 brightness 90%+second group of LEDs L2 10%

Third level: first group of LEDs L1 brightness 80%+second group of LEDs L2 20%

Fourth level: first group of LEDs L1 brightness 70%+second group of LEDs L2 30%

Fifth level: first group of LEDs L1 brightness 60%+second group of LEDs L2 40%

Sixth level: first group of LEDs L1 brightness 50%+second group of LEDs L2 50%

Seventh level: first group of LEDs L1 brightness 40%+second group of LEDs L2 60%

Eighth level: first group of LEDs L1 brightness 30%+second group of LEDs L2 70%

Ninth level: first group of LEDs L1 brightness 20%+second group of LEDs L2 80%

Tenth level: first group of LEDs L1 brightness 90%+second group of LEDs L2 10%

Eleventh level: first group of LEDs L1 brightness 0%+second group of LEDs L2 110%

For example, the fine adjustment module may control current supplied to the first group of LEDs L1 so that the brightness is adjusted to about 70% and control current supplied to the second group of LEDs L2 so that the brightness is adjusted to about 30%. As a result, the fine adjustment module may finely adjust the color temperature.

The plurality of LEDs L may include RGB LEDs. The control unit may control the color and the turn on/off of the plurality of LEDs L to realize various characters, figures, and the like through various colors in a static or dynamic form through the flexible lighting panel A according to this embodiment.

As illustrated in FIG. 7, a thermoplastic resin layer 150 made of a synthetic resin material such as polypropylene, polyester, polyethylene, polyvinyl chloride, or the like may be further provided between the base layer 100 and the black sheet layer 200. Thus, the fundamental structure may be more firmly maintained by the thermoplastic resin layer 150.

### Another Embodiment

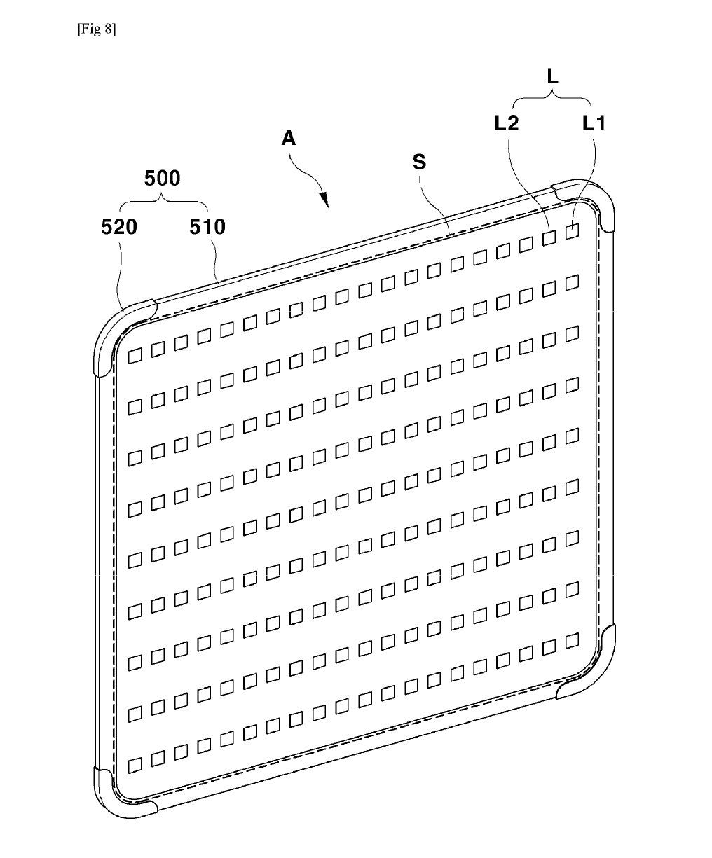

As illustrated in FIGS. 8 to 11, a flexible lighting panel A according to another embodiment of the prevent invention includes a base layer 100, a plurality of LEDs L, a heat dissipating layer 200, a spacer layer 300, a transparent cover layer 400, a fiber layer 600, a finishing member 500, and a control unit (not shown).

First, the base layer 100 will be described.

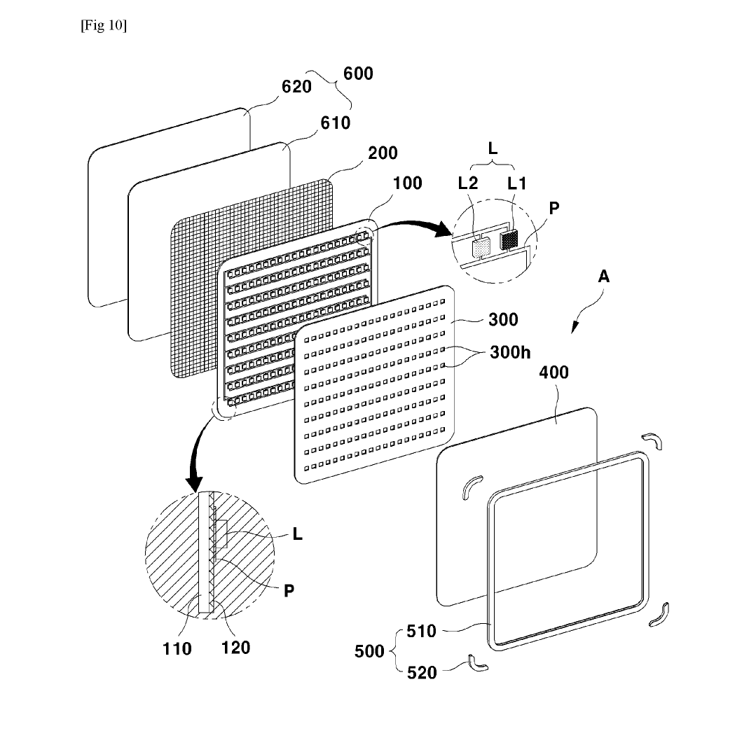

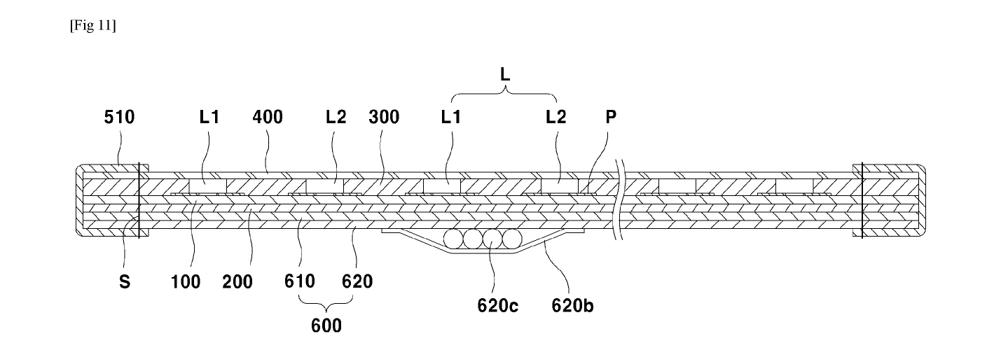

As illustrated in FIG. 10, the base layer 100 may be a flexible plate-shaped portion having one side surface on which a circuit pattern P is disposed and made of a flexible material to mount the plurality of LEDs L. As described above, since the base layer 100 is made of the flexible material, the flexible lighting panel A according to this embodiment may have a flexible property.

For example, as illustrated in FIG. 10, the base layer 100 includes a flexible board 110 made of a flexible synthetic resin material, a silicon layer 120 laminated on at least one side surface of the flexible board 110, and a circuit pattern P formed on a top surface of the silicon layer 120.

The flexible board 110 may have a formation thickness of about 40 μm to about 100 μm, the silicon layer 120 may have a formation thickness of about 20 μm to about 35 μm, the circuit pattern P may have a formation thickness of about 15 μm to about 80 μm, and the silicon layer 120 has shore hardness of 70 to 100.

Since the silicon layer 120 has the formation thickness of 20 μm to about 35 μm and the shore hardness of 70 to 100, an occurrence of cracks may be prevented after the silicon layer 120 is formed. In addition, a pushing phenomenon in which the silicon layer 120 is pushed and thus separated by external force may be prevented so that the circuit pattern P formed on the silicon layer 120 may be stably laminated and fixed in position.

The circuit pattern P may be formed in a desired pattern shape through an etching process after a metal layer is laminated on a top surface of the silicon layer 120 through a roll-to-roll process.

Here, it is preferable that when the board is made of polyethylene terephthalate (PET) or polyethylene naphthalate (PEN), a temperature for the roll-to-roll process is 120° to 170°, and when the board is made of polyimide (PI), a temperature for the roll-to-roll process is 180° to 230°. Also, a process time may be preferably less than 5 minutes.

This is done because, when the roll-to-roll process is performed at an excessively low temperature, the metal layer is not smoothly laminated on the silicon layer 120, and when the roll-to-roll process is performed at an excessively high temperature, the silicon layer 120 is damaged, and thus, the process time is not economical to proceed for 5 minutes or more.

Ink containing an alkyd resin may be applied to the top surface of the silicon layer 120 on which the circuit pattern P is not formed. It is preferable that the ink containing the alkyd resin has a white or black color.

When the ink has the white color, light emitted to a rear surface of the LED L may be totally reflected to enhance light intensity.

When the ink has the black color, the light emitted to the rear surface of the LED L may be partially absorbed to prevent light interference from occurring.

As described above, since the ink containing the alkyd resin is applied to the top surface of the silicon layer 120 on which the circuit pattern P is not formed, the abovementioned advantages may be realized when the spacer layer 300 is not provided.

When a PSR ink is applied, it is confirmed that cracks occurs after the drying. When the ink containing the alkyd resin is applied, it is confirmed that the cracks do not occur after the drying, and thus, it is suitable to the flexible panel.

Next, the plurality of LEDs L will be described.

The plurality of LEDs L is mounted on the base layer 100 so as to be electrically connected to the circuit pattern P.

The plurality of LEDs L may include at least two groups, and each of the groups may have a different color temperature.

The plurality of LEDs L include a first group of LEDs L1 having a color temperature of 2,500 K to 3,500 K and a second group of LEDs L2 having a color temperature of 4,500 K to 6,500 K. For example, the plurality of LEDs L may be constituted by a first group of LEDs L1 having a color temperature of 3,000 K and a second group of LEDs L2 having a color temperature of 5,000 K.

As illustrated in FIG. 10, the first group of LEDs L1 and the second group of LEDs L2 may be lattice-arranged adjacent to each other.

The plurality of LEDs L may include RGB LEDs.

Next, the heat dissipating layer 200 will be described.

The heat dissipating layer 200 may be laminated on the other side surface of the base layer 100 to dissipate heat generated from the plurality of LEDs L. For example, the heat dissipating layer 200 may have a plate-like structure having a net structure or a honeycomb structure, which is made of a copper or aluminum material.

As described above, since the heat dissipating layer 200 is formed with the plate-like shape having the net structure or the honeycomb structure, a heat dissipating area may increase to improve an effect in which heat of the LEDs L is naturally dissipated through the through-holes so that the heat is smoothly dissipated.

Next, the spacer layer 300 will be described.

The spacer layer 300 is laminated on the top surface of the base layer 100 except for the plurality of LEDs L and has through-holes 300h corresponding to positions of the plurality of LEDs L.

The spacer layer 300 may be attached to the top surface of the base layer 100 through a unit such as an adhesive.

To prevent the transparent cover layer 400 from being lift by the formation height of the LED L, it is preferable that the spacer layer 300 is formed with a formation thickness corresponding to the formation height of the LED L.

It is preferable that a surface color of the spacer layer 300 is white or black.

When the spacer layer 300 has the white surface color, light emitted to the rear surface of the LED L may be totally reflected to enhance light intensity.

When the spacer layer 300 has the black surface color, light emitted to the rear surface of the LED L may be partially absorbed to prevent light interference from occurring.

A thermoplastic resin layer made of a synthetic resin material such as polypropylene, polyester, polyethylene, polyvinyl chloride, or the like may be further provided between the base layer 100 and the spacer layer 300. Thus, the fundamental structure may be more firmly maintained by the thermoplastic resin layer.

In the flexible lighting panel A according to this embodiment, the spacer layer 300 may be selectively provided. Thus, the flexible lighting panel A may be provided with a structure without the spacer layer 300.

Next, the transparent cover layer 400 will be described.

The transparent cover layer 400 is a portion that covers and seals the spacer layer 300 and the LEDs L. It is preferable that the transparent cover layer 400 is made of a material having a high light-transmitting property and a superior waterproof property.

For example, the transparent cover layer 400 may be made of a material in which at least one synthetic fiber such as polypropylene, polyester, polyethylene, polyvinyl chloride, and the like is mixed.

The transparent cover layer 400 may be attached in a lamination manner.

A UV blacking agent may be applied inside the transparent layer 400, or the transparent layer 40 in itself may include the UV blocking agent. Thus, the transparent cover layer 300 may be prevented from be discolored by sunlight even though the transparent cover layer 300 is used for a long time in the outdoor space.

A phosphor resin may be applied inside the transparent cover layer 400, or the transparent cover layer 400 in itself may include the phosphor resin. Thus, a color temperature (3,000 K to 6,000 K) may be set to a desired temperature, and a color rendering index may increase so that light near to natural light is irradiated.

The UV blocking agent and the phosphor resin may be applied together inside the transparent cover layer 400, or the transparent cover layer 400 in itself may include the UV blocking agent and the phosphor resin.

Next, the fiber layer 600 will be described.

The fiber layer 600 may be a portion that is laminated on the other side of the heat dissipating layer 200 and include a first fiber layer 610 and a second fiber layer 620.

One or both of the first and second fiber layers 610 and 620 may be is flame-retarded or waterproofed to give a strong heat-resistant property and a waterproof property.

A power supply electrode 620a, which supplies power to the plurality of LEDs L, a power supply cable 630c connected to the power supply electrode 620a, and a cable fixing tool 630b for fixing and supporting a portion of the power supply cable 630c connected to the power supply electrode 620a are disposed on a bottom surface of the second fiber layer 620.

The cable fixing tool 630b may prevent an end of the power supply cable 630c from being separated from the power supply electrode 620a by pulling the power supply cable 630c.

Next, the finishing member 500 will be described.

The finishing member 500 may include a finishing taping member 510 made of a cloth material, which entirely surrounds edges of the base layer 100, the heat dissipating layer 200, the spacer layer 300, the transparent cover layer 400, and the fiber layer 600, and a finishing bracket 520 made of a metal material, which protects each of corner portions.

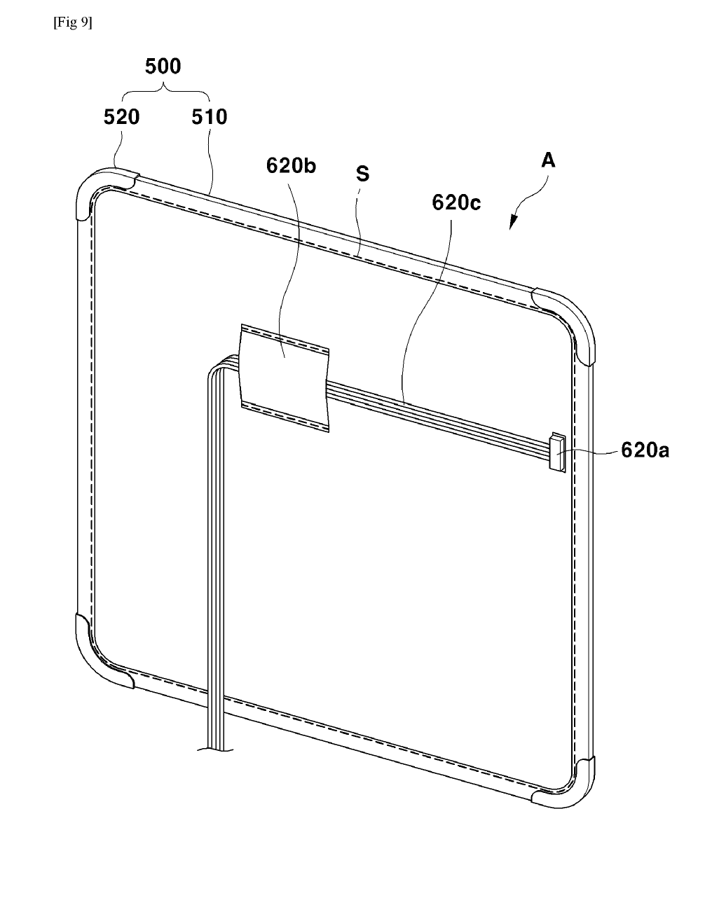

Each of the corner portions of the base layer 100, the heat dissipating layer 200, the spacer layer 300, the transparent cover layer 400, and the fiber layer 600 may have a rounded or chamfered shape. For example, the corner portion may be easily and quickly stapled by using a stapling thread S due to the shape as illustrated in FIGS. 8 and 9.

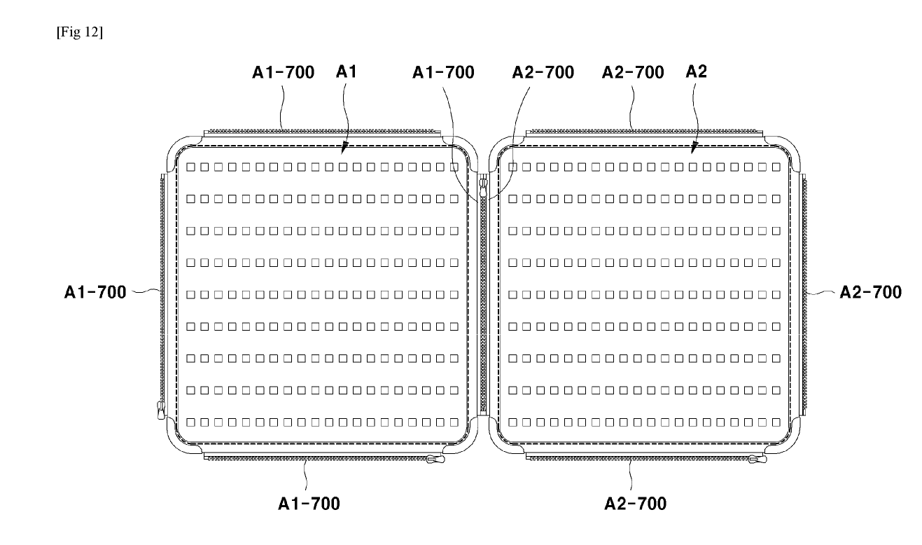

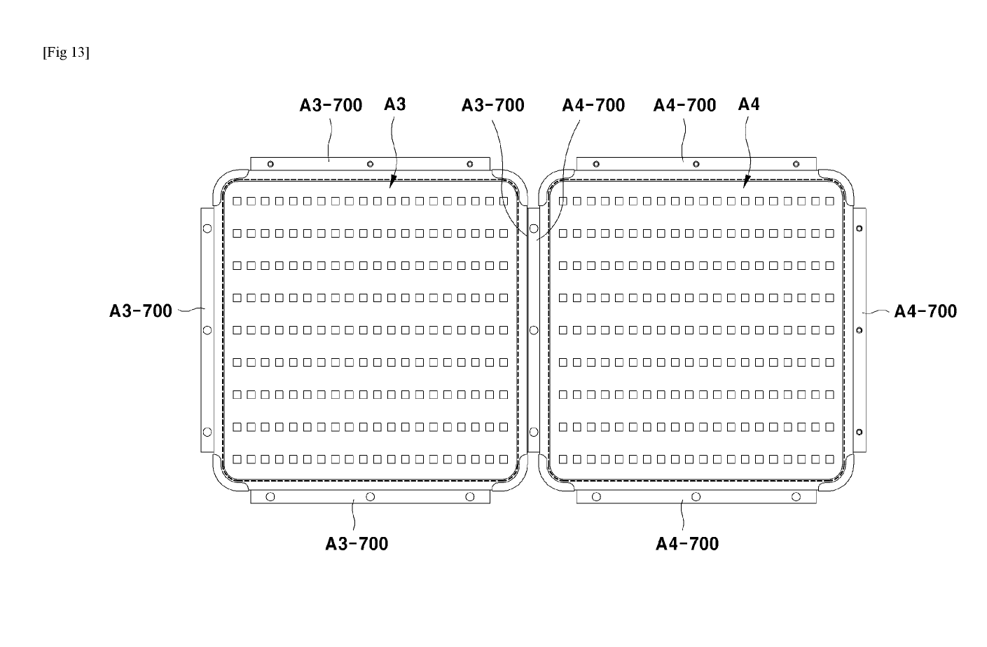

As illustrated in FIGS. 12 and 13, the finishing member 500 may include a connection unit for connecting the flexible lighting panels, which are adjacent to each other, to each other.

For example, as illustrated in FIG. 12, the connection unit may include zippers A1-700 and A2-700. The zipper A1-700 disposed on the finishing member of one flexible lighting panel Al and the zipper A2-700 disposed on the finishing member of the other flexible lighting panel A2 may be connected to each other to connect the plurality of flexible lighting panels Al and A2 to each other.

Also, for example, as illustrated in FIG. 13, the connection unit may include snap fasteners A3-700 and A4-700. A snap fastener A3-700 disposed on the finishing member of one flexible lighting panel A3 and the snap fastener A4-700 disposed on the finishing member of the other flexible lighting panel A4 may be connected to each other to connect the plurality of flexible lighting panels A3 and A4 to each other.

As described above, the plurality of flexible lighting panels may be connected to each other through the connection unit to provide light having a wide area.

Next, the control unit will be described.

The control unit (not shown) may be built in the flexible lighting panel A of this embodiment or be connected to the flexible lighting panel A of this embodiment through a separate cable.

The control unit may control the LEDs L to adjust the color temperatures of the first group of LEDs L1 having the color temperature of 2,500 K to 3,500 K and the second group of LEDs having the color temperature of 4,500 K to 6,500 K. Thus, colors of the first group of LEDs L1 having the color temperature of 2,500 K to 3,500 K and the second group of LEDs having the color temperature of 4,500 K to 6,500 K may be mixed with each other to realize various color temperatures.

The control unit may include a level adjustment module and a fine adjustment module. For example, when the LEDs include the first group of LEDs L1 having the color temperature of 3,000 K and the second group of LEDs L2 having the color temperature of 5,000 K, the level adjustment module may control the color temperature by following levels.

First level: first group of LEDs L1 brightness 100%+second group of LEDs L2 0%

Second level: first group of LEDs L1 brightness 90%+second group of LEDs L2 10%

Third level: first group of LEDs L1 brightness 80%+second group of LEDs L2 20%

Fourth level: first group of LEDs L1 brightness 70%+second group of LEDs L2 30%

Fifth level: first group of LEDs L1 brightness 60%+second group of LEDs L2 40%

Sixth level: first group of LEDs L1 brightness 50%+second group of LEDs L2 50%

Seventh level: first group of LEDs L1 brightness 40%+second group of LEDs L2 60%

Eighth level: first group of LEDs L1 brightness 30%+second group of LEDs L2 70%

Ninth level: first group of LEDs L1 brightness 20%+second group of LEDs L2 80%

Tenth level: first group of LEDs L1 brightness 10%+second group of LEDs L2 90%

Eleventh level: first group of LEDs L1 brightness 0%+second group of LEDs L2 110%

For example, the fine adjustment module may control current supplied to the first group of LEDs L1 so that the brightness is adjusted to about 70% and control current supplied to the second group of LEDs L2 so that the brightness is adjusted to about 30%. As a result, the fine adjustment module may finely adjust the color temperature.

When the plurality of LEDs L includes RGB LEDs, the control unit may control the color and the turn on/off of the plurality of RGB LEDs L to realize various characters, figures, and the like through various colors in a static or dynamic form through the flexible lighting panel A according to this embodiment.

While the present invention has been particularly shown and described with reference to the accompanying drawings according to exemplary embodiments, it will be understood by those of ordinary skill in the art that various changes in form and details may be made therein without departing from the spirit and scope of the present invention as defined by the following claims. Therefore, the protective range of the present invention should be construed by claims described to include many modified examples.

1. A flexible lighting panel comprising:
a base layer having one side surface on which a circuit pattern is disposed and made of a flexible material;
a plurality of LEDs mounted on one side surface of the base layer; and
a heat dissipating layer laminated on the other side surface of the base layer.

2. The flexible lighting panel of claim 1, wherein the heat dissipating layer has a plate-like structure having a net structure or a honeycomb structure.

3. The flexible lighting panel of claim 1, wherein the heat dissipating layer is made of a copper or aluminum material.

4. The flexible lighting panel of claim 1, wherein at least one fiber layer is laminated on the other side surface of the heat dissipating layer.

5. The flexible lighting panel of claim 4, wherein the fiber layer is treated to be flame-retarded or waterproofed.

6. The flexible lighting panel of claim 1, wherein the plurality of LEDs comprise at least two groups, and each of the groups has a different color temperature.

7. The flexible lighting panel of claim 6, wherein the plurality of LEDs comprise a first group of LEDs having a color temperature of 2,500 K to 3,500 K and a second group of LEDs having a color temperature of 4,500 K to 6,500 K, and the first group of LEDs and the second group of LEDs are lattice-arranged adjacent to each other.

8. The flexible lighting panel of claim 6, wherein the plurality of LEDs comprise a first group of LEDs having a color temperature of 2,800 K and a second group of LEDs having a color temperature of 6,500 K, and
the flexible lighting panel further comprises a control unit comprising a level adjustment module configured to adjust the color temperatures of the first and second groups in stages and a fine adjustment module configured to control current supplied to the first and second groups, which are adjusted in level by the level adjustment module to finely adjust the color temperatures.

9. The flexible lighting panel of claim 1, wherein the plurality of LEDs comprise RGB LEDs, and
the flexible lighting panel further comprises a control unit configured to control colors and turn on/off of the plurality of LEDs.

10. The flexible lighting panel of claim 1, further comprising:
a spacer layer laminated on a top surface of the base layer except for the plurality LEDs; and
a transparent cover layer configured to cover and seal the spacer layer and the LEDs.

11. The flexible lighting panel of claim 10, wherein a UV blocking agent or a phosphor resin is applied inside the transparent cover layer.

12. The flexible lighting panel of claim 10, wherein the spacer layer has a thickness corresponding to a formation height of each of the LEDs.

13. The flexible lighting panel of claim 1, wherein each of the base layer and the heat dissipating layer has a flat rectangular shape of which corner portions are rounded or chamfered, and
the flexible lighting panel further comprises a finishing member configured to surround edges of the base layer and the heat dissipating layer.

14. The flexible lighting panel of claim 13, wherein the finishing member comprises a connection unit connecting the adjacent flexible lighting panels to each other.

15. The flexible lighting panel of claim 1, wherein the base layer comprises:
a flexible board made of a flexible synthetic resin material;
a silicon layer laminated on at least one side surface of the flexible board; and
a circuit pattern formed on a top surface of the silicon layer.

16. The flexible lighting panel of claim 15, wherein the silicon layer has shore hardness of 70 to 100.

17. The flexible lighting panel of claim 15, wherein the circuit pattern is formed through an etching process after a meal layer is laminated on the top surface of the silicon layer through a roll-to-roll process.

18. The flexible lighting panel of claim 17, wherein, when the board is made of polyethylene terephthalate (PET) or polyethylene naphthalate (PEN), a temperature for the roll-to-roll process is 120° to 170°, and when the board is made of polyimide (PI), a temperature for the roll-to-roll process is 180° to 230°.

19. The flexible lighting panel of claim 15, wherein ink containing an alkyd resin is applied to the top surface of the silicon layer on which the circuit pattern is not formed.

20. The flexible lighting panel of claim 15, wherein the silicon layer has a formation thickness of 20 μm to 35 μm.

21. A flexible lighting panel comprising:
a base layer having a top surface on which a circuit pattern is disposed and made of a flexible material;
a plurality of LEDs mounted on the base layer so as to be electrically connected to the circuit pattern;
a black sheet layer laminated on the top surface of the base except for the plurality of LEDs; and
a transparent cover layer configured to cover and seal the black sheet and the LEDs.

22. The flexible lighting panel of claim 21, wherein the base layer is made of a fiber material.

23. The flexible lighting panel of claim 22, wherein the base layer is treated to be flame-retarded or waterproofed.

24. The flexible lighting panel of claim 21, wherein the transparent cover layer comprises a UV blocking agent.

25. The flexible lighting panel of claim 21, wherein the plurality of LEDs comprise at least two groups, and each of the groups has a different color temperature.

26. The flexible lighting panel of claim 25, wherein the plurality of LEDs comprise a first group of LEDs having a color temperature of 2,500 K to 3,500 K and a second group of LEDs having a color temperature of 4,500 K to 6,500 K, and the first group of LEDs and the second group of LEDs are lattice-arranged adjacent to each other.

27. The flexible lighting panel of claim 21, wherein each of the base layer, the black sheet layer, and the transparent cover layer has a flat rectangular shape of which corner portions are rounded or chamfered, and
the flexible lighting panel further comprises a finishing member configured to surround edges of the base layer, the black sheet layer, and the transparent cover layer.

28. The flexible lighting panel of claim 21, wherein a power supply electrode configured to supply power to the plurality of LEDs, a power supply cable connected to the power supply electrode, and a cable fixing tool configured to fix and support a portion of the power supply cable connected to the power supply electrode are disposed on a bottom surface of the base layer.

29. The flexible lighting panel of claim 21, wherein the plurality of LEDs comprise a first group of LEDs having a color temperature of 2,800 K and a second group of LEDs having a color temperature of 6,500 K, and
the flexible lighting panel further comprises a control unit comprising a level adjustment module configured to adjust the color temperatures of the first and second groups in stages and a fine adjustment module configured to control current supplied to the first and second groups, which are adjusted in level by the level adjustment module to finely adjust the color temperatures.

30. The flexible lighting panel of claim 21, wherein the plurality of LEDs comprise RGB LEDs, and
the flexible lighting panel further comprises a control unit configured to control colors and turn on/off of the plurality of LEDs.

31. The flexible lighting panel of claim 21, wherein, in order to prevent the transparent cover layer from being lift by a formation height of each of the LEDs, the black sheet layer has a thickness corresponding to the formation height of the LED.

32. The flexible lighting panel of claim 21, wherein a thermoplastic resin layer is further disposed between the base layer and the black sheet layer.
